(19) United States
(12) Patent Application Publication
(10) Pub. No.: US 2007/0207931 A1
(43) Pub. Date: Sep. 6, 2007

(54) Grooved porous surface, production method and application in heat transfer

(76) Inventors: Petri Rissanen, Pori (FI); Liangyou Tang, Shanghai (CN)

Correspondence Address: HODGSON RUSS LLP;THE GUARANTY BUILDING, 140 PEARL STREET, SUITE 100, BUFFALO, NY, 14202-4040, US

(21) Appl. No.: 11/644,081

(22) Filed: Dec. 22, 2006

Related U.S. Application Data
(60) Provisional application No. 60/753,123, filed on Dec. 22, 2005.

(51) Int. Cl. H01L 39/24

(52) U.S. Cl. 505/430

(57) ABSTRACT

A heat transfer tube having surface enhancements so as to improve the thermal performance and increase the heat transfer capacity. The heat transfer tube has an inner surface having a layer of sintered, soldered or brazed metal powder thereon.

### CROSS-REFERENCE TO RELATED APPLICATIONS

This application is based upon and claims priority to U.S. Patent Application No. 60/753,123 filed Dec. 22, 2005. The contents of which are incorporated herein by reference.

### BACKGROUND OF THE INVENTION

1. Field of the Invention

The present invention relates generally to heat transfer tubes and HVACR (heating, ventilation, air conditioning and refrigeration) tubes. More particularly, the invention relates to a heat transfer tube that has an enhanced surface that is capable of improved heat transfer performance.

2. Description of the Related Art

The heat transfer performance of a heat transfer tube having enhancements is known to those skilled in the art to be superior to a plain walled tube. Surface enhancements have been applied to both internal and external tube surfaces, including ribs, fins, coatings, and inserts. All enhancement designs attempt to increase the heat transfer surface area of the tube.

Conventionally, heat transfer pipes are manufactured from inner-grooved tubes. These heat transfer pipes suffer from an increase in thermal resistance with low heat loads, which results in an increased temperature of the cooled device, e.g., electrical components. This increased temperature reduces performance of the device and in the case of electrical components, it reduces the component life time and limits the use of the heat pipes in low power applications. Accordingly, there is a need for a heat pipe with improved thermal performance and increased heat transfer capacity.

### SUMMARY OF THE INVENTION

The heat transfer tube of the present invention has an internal surface that is configured to enhance the heat transfer performance of the tubes. The present invention meets the above-described need by providing a heat transfer tube where the surface of the tube is enhanced with sintered, brazed or soldered powder to form a grooved porous surface tube that is suitable for use in heat transfer applications.

In the method of this invention, the tube is formed from a strip of a suitable metal such as copper or copper alloy. A roller or other device for forming ribs or cross hatches produces grooves on the surface of the strip, thereby enhancing the surface. The grooves are longitudinal ribs that are cross-hatched at an angle to the longitudinal axis, thereby forming an array of projections on the surface of the tube.

The strip with the surface enhancement grooves further has metal powder joined on the surface. The metal powder can be joined on the surface of the enhanced strip by brazing of the powder, sintering of the powder or soldering of the powder.

### BRIEF DESCRIPTION OF THE DRAWINGS

FIG. 1 is an elevational view of the heat transfer tube of the present invention showing a cutaway portion of the tube.

FIG. 2 is a schematic perspective view illustrating a method of forming the tube by impressing a pattern on a surface of a flat sheet before forming the flat sheet into the tube with the surface becoming the inner surface of the tube.

FIG. 3 depicts a thermal resistance vs. heat load curve comparing the thermal resistance of a prior art heat pipe and a heat pipe of the present invention.

### DETAILED DESCRIPTION OF THE INVENTION

The present invention combines drawn or rolled surface enhancements in connection with powder that is sintered, brazed or soldered to the surface of a tube to form a grooved, porous surface tube for use in heat transfer applications. The applications may include two phase refrigerants in typical HVACR systems. The invention may also be used as a heat transfer tube that functions as a heat sink for electronic components such as CPU's. The grooved, porous surface is designed to increase heat transfer capacity.

The tube of the present invention can be formed initially from a strip of a suitable metal such as copper. The copper strip may be provided with an enhanced surface by a roller or other device for forming ribs or cross hatches on the surface of the strip. The grooves can be formed longitudinally with respect to the finished tube and/or at an angle to the longitudinal axis as will be evident to those of ordinary skill in the art based on this disclosure. One exemplary pattern may include longitudinal ribs formed between grooves. The longitudinal ribs may then be cross hatched at an angle to the longitudinal axis to form an array of projections on the surface of the tube.

Referring to FIG. 1, tube 10 is formed by a metal such as copper or copper alloy, or other heat conductive metal. Tube 10 is cylindrical with an outside diameter, inside diameter, and corresponding wall thickness. The inner surface is formed with an internal surface enhancement 13. The heat transfer tube of the present invention can be formed by roll embossing the enhancement pattern 13 on one surface of a copper or copper alloy strip.

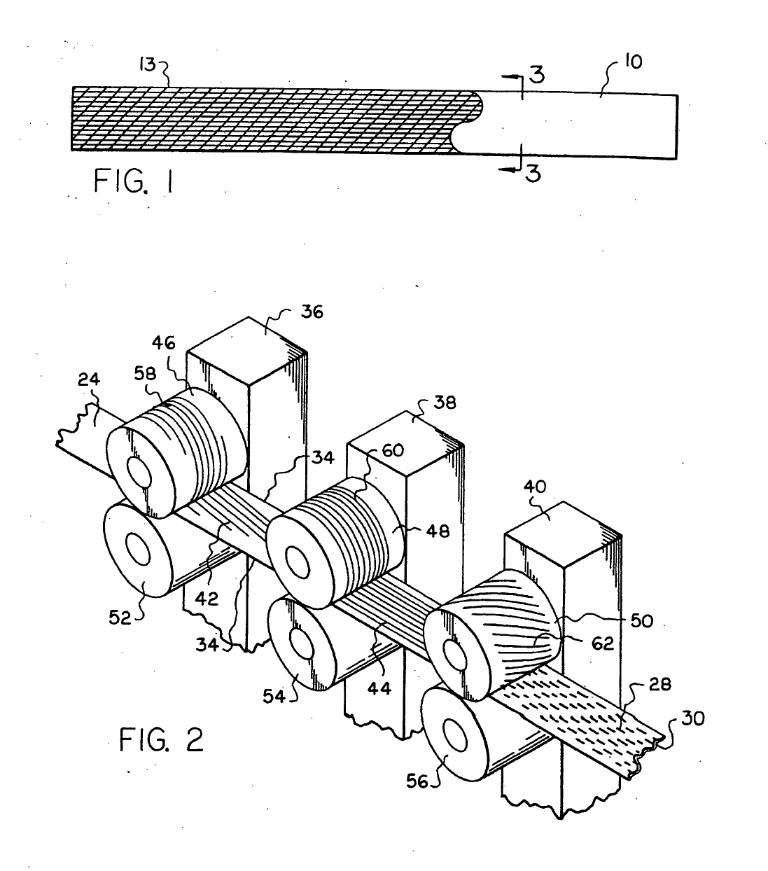

FIG. 2 illustrates the embossing process. Three roll embossing stations 36, 38, and 40 are positioned in the production line for forming or embossing first, second, and third enhancements or patterns 42, 44, and 28 respectively onto the surface 24.

Each embossing station 36, 38, and 40 has a patterned enhancement roller 46, 48, and 50 respectively and a plain or unpatterned backing roller 52, 54, and 56 respectively. The backing and patterned rollers in each station are pressed together with sufficient force, by suitable conventional means (not shown) to cause, for example, patterned surface 58 on roller 46 to be impressed into the surface 24 of strip 30 thus forming enhancement pattern 42 on the strip 30.

The strip with surface enhancements may then have powder joined on its surface. The powder is typically a metal powder, and one example of a suitable powder is copper powder. Other suitable powders include copper alloys such as brass, phosphorus-bearing copper (e.g. DHP), silver-bearing copper and the like.

The copper powder coating can be joined on the surface of the enhanced strip by optionally mixing the copper powder with a brazing or soldering material, e.g., Sn-alloy powder or Cu—Ni—Sn—P alloy powder and especially OKC 600 powder. Powders, which are joined on the surface, can be applied to the surface by, e.g., spraying, painting or as a mixture of the powders by pouring, and then calibrating the layer thickness.

The thickness of the powder coating on the surface enhanced heat transfer tube is between 1-250 μm. The powder coating is present in an amount from 3-750 g/m² of tube surface. In this invention, the powder grain size is 1-250 μm.

The following methods may be used to produce the grooved, porous surface of the present invention:
1. Brazing of Powder

Copper powder mixed with organic binder and some brazing powder is applied to a copper strip or tube surface. The powder can be applied by spraying, painting or drawing in one step or in different steps. Copper powder particles are brazed to each other and the copper surface by annealing at a temperature higher than 450 degrees Celsius and especially at 600 to 700 degrees Celsius for one to ten minutes. It has been found that 620 to 650 degrees Celsius is a suitable temperature. The strip, which has been brazed to join the powder, may also be welded or brazed into a tube. The brazing can be done at the same time as the brazing of the powder or in a separate step. The binder is removed by annealing at about 100 degrees Celsius to 500 degrees Celsius before brazing.
2. Sintering of Powder

Copper powder mixed with organic binder is applied to a copper strip or tube surface. It can be applied by spraying, painting or drawing in one step or in different steps. Copper powder particles are sintered to each other and the copper surface by annealing at about 700 degrees Celsius to 1050 degrees Celsius for ten to one-hundred minutes depending on powder size and temperature. The sintered strip can then be welded or brazed into a tube. The binder is removed before sintering by annealing at about 100 to 500 degrees Celsius.
3. Soldering of Powder

Copper powder mixed with organic binder is applied to a copper strip or tube surface. It can be applied by, e.g., spraying, painting or drawing in one step or in different steps. Copper powder particles are soldered to each other and the copper surface by annealing at about 190 degrees Celsius to 450 degrees Celsius for one to ten minutes. The soldered strip can then be welded into a tube. The binder is removed before soldering and welding at about 100 to 500 degrees Celsius.

In the cases described above, the copper surface has surface enhancements (any possible surface except a smooth wall). For example, there can be grooves, pits, notches or pores on the copper surface. The surface enhancements can be provided by rolling or drawing as described above.

After the powder is joined to the surface of the strip, the strip may be formed into a tube by drawing or rolling as will be evident to those of ordinary skill in the art based on this disclosure.

The powder coated tubes of the present invention can be used to manufacture heat pipes and HVACR tubes.

The present invention may be practiced in at least the following ways. First, the grooved, porous surface tube of the present invention can be produced by forming surface enhancements on the strip, coating the strip with powder, joining the powder to the strip by brazing, sintering or soldering and then forming the strip into a tube by welding or brazing. Alternatively, the present invention may also be practiced by manufacturing the tube with surface enhancements, coating the tube with powder and then joining the powder to the tube by brazing, sintering or soldering.

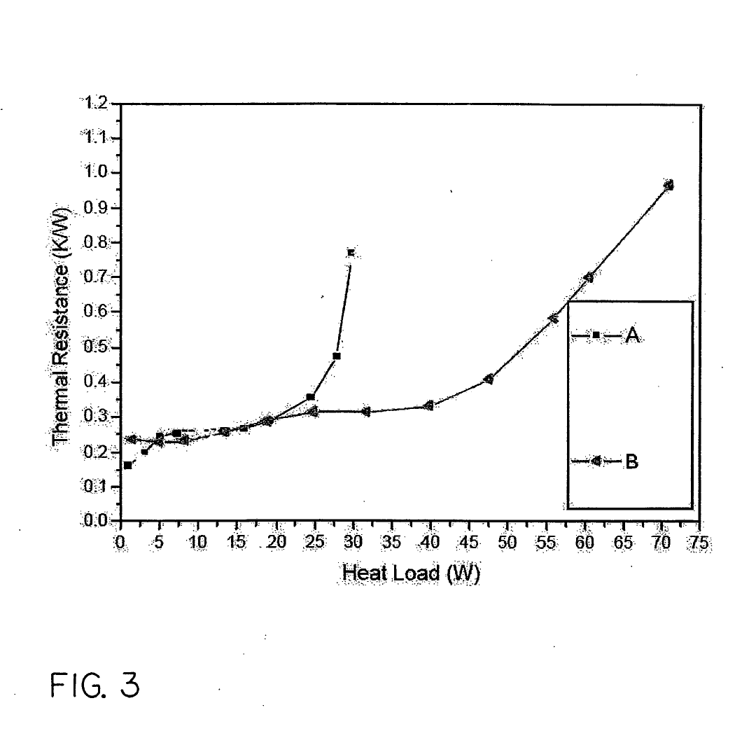

FIG. 3 depicts a typical thermal resistance vs. heat load curve for heat pipes manufactured from axial inner-grooved tubes. The curve labelled A shows the thermal resistance curve for an axial inner-grooved tube without powder-coating. The curve labelled B shows the thermal resistance curve for an axial inner-grooved tube with powder-coating. As shown in the figure, the pipes with powder-coating achieve much better thermal performance on high heat loads. The improved thermal performance is due to the improved wetting and capillary flow resulting from the larger surface area.

While the invention has been described in connection with certain embodiments, it is not intended to limit the scope of the invention to the particular forms set forth, but, on the contrary, it is intended to cover such alternatives, modifications, and equivalents as may be included within the spirit and scope of the invention as defined by the appended claims.

What is claimed is:

1. A heat transfer tube, comprising:
a tubular member having an inner surface defining an inner diameter;
said tubular member having surface enhancements on said inner surface; and
said inner surface having a metal powder coating joined onto the surface enhanced inner surface.

2. The heat transfer tube of claim 1, wherein the surface enhancements are selected from the group consisting of grooves, ribs, pits, notches and pores.

3. The heat transfer tube of claim 1, wherein the metal powder is joined onto the surface enhanced inner surface by brazing.

4. The heat transfer tube of claim 1, wherein the metal powder is joined onto the surface enhanced inner surface by soldering.

5. The heat transfer tube of claim 1, wherein the metal powder is joined onto the surface enhanced inner surface by sintering.

6. The heat transfer tube of claim 1, wherein the metal powder is comprised of copper.

7. The heat transfer tube of claim 1, wherein the metal powder is comprised of copper alloy.

8. The heat transfer tube of claim 3, wherein the metal powder includes a brazing material.

9. The heat transfer tube of claim 8, wherein the brazing material is comprised of Cu—Ni—Sn—P alloy.

10. The heat transfer tube of claim 4, wherein the metal powder includes a soldering material.

11. The heat transfer tube of claim 10, wherein the soldering material is comprised of tin alloy.

12. The heat transfer tube of claim 1, wherein the thickness of the metal powder coating on said inner surface is 1-250 μm.

13. The heat transfer tube of claim 1, wherein the amount of metal powder present on said inner surface is 3-750 g/m² of the tube surface.

14. The heat transfer tube of claim 1, wherein the grain size of the metal powder is 1-250 μm.

15. A method for producing a heat transfer tube having a grooved porous surface comprising:
(a) forming in an inner surface for the tube at least one enhancement;
(b) coating a metal powder onto said inner surface; and,
(c) joining the metal powder onto said inner surface.

16. The method of claim 15, wherein the metal powder is selected from the group consisting of copper and copper alloys.

17. The method of claim 15, wherein the metal powder coating joined onto the inner surface of the heat transfer tube has a thickness of 1-250 μm.

18. The method of claim 15, wherein the metal powder joined onto the inner surface of the heat transfer tube is present in an amount of from 3-750 g/m² of tube surface.

19. The method of claim 15, wherein the metal powder joined onto the inner surface of the heat transfer tube has a powder grain size of 1-250 μm.

20. The method of claim 15, wherein the step of joining the metal powder further comprises mixing the metal powder with an organic binder and optionally a brazing powder or soldering powder.

21. The method of claim 15, wherein the step of joining the metal powder further comprises spraying, painting or drawing.

22. The method of claim 20 further comprising removing the binder by annealing at 100-500° C.

23. The method of claim 22, wherein the step of joining the metal powder further comprises brazing the metal powder.

24. The method of claim 23, wherein the step of brazing further comprises annealing at 600 to 700° C. for one to ten minutes.

25. The method of claim 23, wherein the step of brazing further comprises annealing at 620 to 650° C. for one to ten minutes.

26. The method of claim 22, wherein the step of joining the metal powder further comprises sintering the metal powder.

27. The method of claim 26, wherein the step of sintering further comprises annealing at 700-1050° C. for 10-100 minutes.

28. The method of claim 22, wherein the step of joining the metal powder further comprises soldering the metal powder.

29. The method of claim 28, wherein the step of soldering the metal powder further comprises soldering with an Sn-alloy.

30. The method of claim 28, wherein the step of soldering further comprises soldering at 190 to 450° C. for 1-10 minutes.
